(19) United States
(12) Patent Application Publication
(10) Pub. No.: US 2017/0181266 A1
(43) Pub. Date: Jun. 22, 2017

(54) ELECTRONIC CIRCUIT BOARD SHIELDING WITH OPEN WINDOW HEAT TRANSFER PATH

(71) Applicant: THOMSON LICENSING, Issy de Moulineaux (FR)

(72) Inventors: Mickey Jay Hunt, Camby, IN (US); Joseph Lee Carpenter, Noblesville, IN (US); Darin Bradley Ritter, Indianapolis, IN (US)

(21) Appl. No.: 14/978,682

(22) Filed: Dec. 22, 2015

(51) Int. Cl. H05K 1/02; H05K 7/20

(52) U.S. Cl. CPC H05K 1/0204; H05K 1/0209; H05K 7/20409; H05K 2201/066; H05K 2201/09036

(57) ABSTRACT

An improved heat transfer system for components an electronic device is provided. The electronic device includes a printed circuit board, a component shield and a heatsink or heat spreader. An open heat transfer window is positioned in the component shield so as to enable a depression in the heat sink to pass through the window and directly contact a thermal pad for a component requiring heat dissipation. A grounding connection between the shield and the heatsink is provided to prevent radiation loss in the radio frequency shielding capability resulting from the creation of the open heat transfer window in the shield.

### BACKGROUND

1. Field of Technology

The present principles relate to electronic devices with circuit boards having one or more components requiring heat dissipation. More particularly, it relates to a printed circuit board shield design for increasing component heat transfer/dissipation away from the components requiring the same.

2. Discussion of Related Art

Thermal management remains a significant challenge in electronic devices such as, for example, set top boxes and network gateways. With the introduction of more components having increased processing capabilities and increased functionalities, which tend to produce more heat, the need for an improved thermal management system exists.

An additional complication in the trend of electronic devices is the need to reduce the size of the device due to consumer preference. This trend for compactness also makes thermal management a challenge, because greater compactness with an increased number of internal components generally results in a higher concentration of heat.

Proper thermal contact between a thermal pad on a circuit board component and a heatsink improves heat dissipation from the circuit board. Additionally, heat spreaders (i.e., heatsinks) with associated shields (e.g., Radio Frequency or Ground shields) are often used to contain or prevent frequency interference generated by the electronic components on the circuit board, and can also operate to improve heat dissipation from one ore more electronic components. However, those of skill in the art will appreciate that existing structure and techniques for securing a shield with an associated heatsink against the thermal pad of a particular component results in an insufficient grounding of the heatsink within the electronic device.

Therefore, a need exists to provide sufficient grounding of the heatsink to the printed circuit board through the component shield without negatively impacting the required heat dissipation of one or more components contained within the confines of the shield.

### SUMMARY

Embodiments of the disclosure provide an electronic device having electronic device having a printed circuit board having one or more electronic components requiring heat dissipation. The electronic device includes a shield positioned on at least a part of the printed circuit board and having one or more heat transfer windows positioned over those electronic components requiring heat dissipation. A heatsink has one or more depressions configured to be positioned over and pass through the one or more heat transfer windows in the shield.

Embodiments of the disclosure are directed to an electronic device having a printed circuit board having one or more electronic components, and a shield configured to be positioned on at least a part of the printed circuit board. The shield includes at least one open heat transfer window positioned to be aligned with at least one electronic component requiring heat dissipation, and a ground connection associated with the at least one open heat transfer window. A heatsink has at least one depression configured to be aligned with the at least one open heat transfer window. In an embodiment, the ground connection can be formed by a plurality of ground fingers disposed at a selected spacing around the one or more heat transfer window that operates to block the applicable radiation wavelengths deemed to be detrimental, thus maintaining the shield's integrity for its intended purpose, while still providing the heat transfer window.

### BRIEF DESCRIPTION OF THE DRAWINGS

A more detailed understanding of the invention may be had from the following description, in conjunction with the accompanying drawings, wherein:

FIG. 1 is an exploded view of an electronic device according to the prior art;

FIG. 2 is a partially assembled view of the electronic device of FIG. 1, according to the prior art;

FIG. 3 is an enlarged partial cross section of the component to heatsink connection for the prior art electronic device of FIGS. 1 and 2;

FIG. 4 is an exploded view of an electronic device according to an implementation of the present principles;

FIG. 5 is a partially assembled view of the electronic device of FIG. 4, according to an implementation of the present principles;

FIG. 6 is an enlarged view of the open window of the component shield of the electronic device, according to an implementation of the present principles;

FIG. 7A shows an enlarged side view of the open widow of the component shield of the fully assembled electronic device shown according to an implementation of the present principles; and

FIG. 7B shows a cross sectional view of the enlarged side view shown in FIG. 7A of the open widow of the component shield of the fully assembled electronic device shown according to an implementation of the present principles.

### DETAILED DESCRIPTION

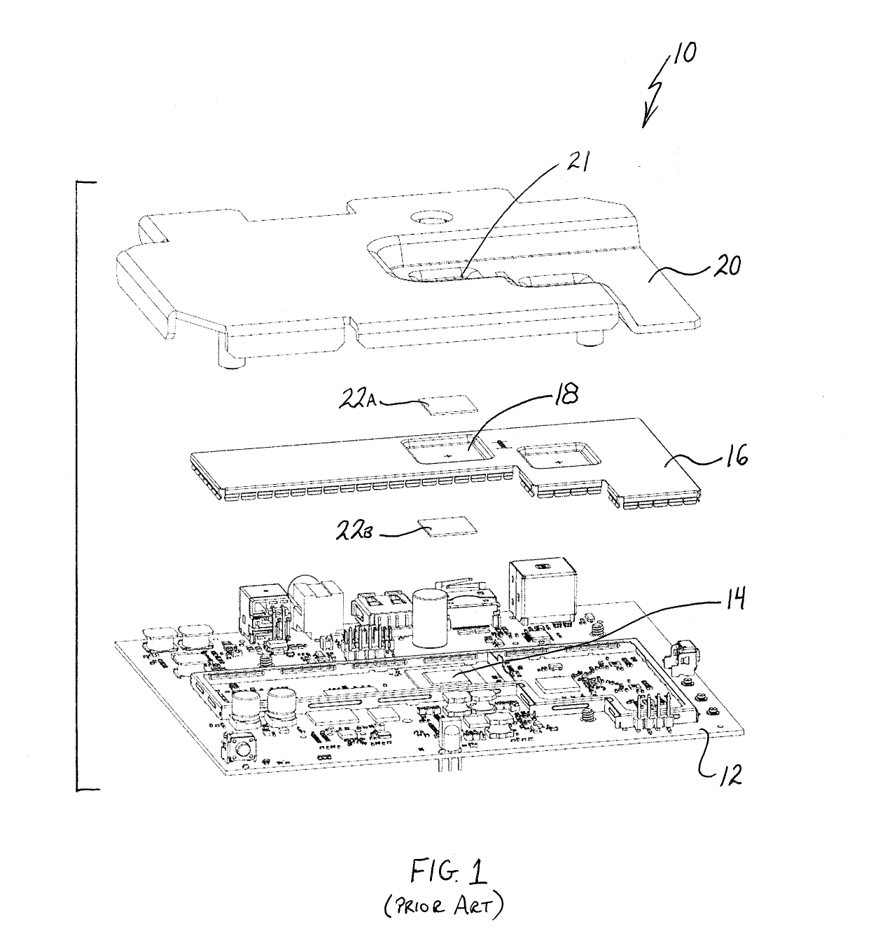

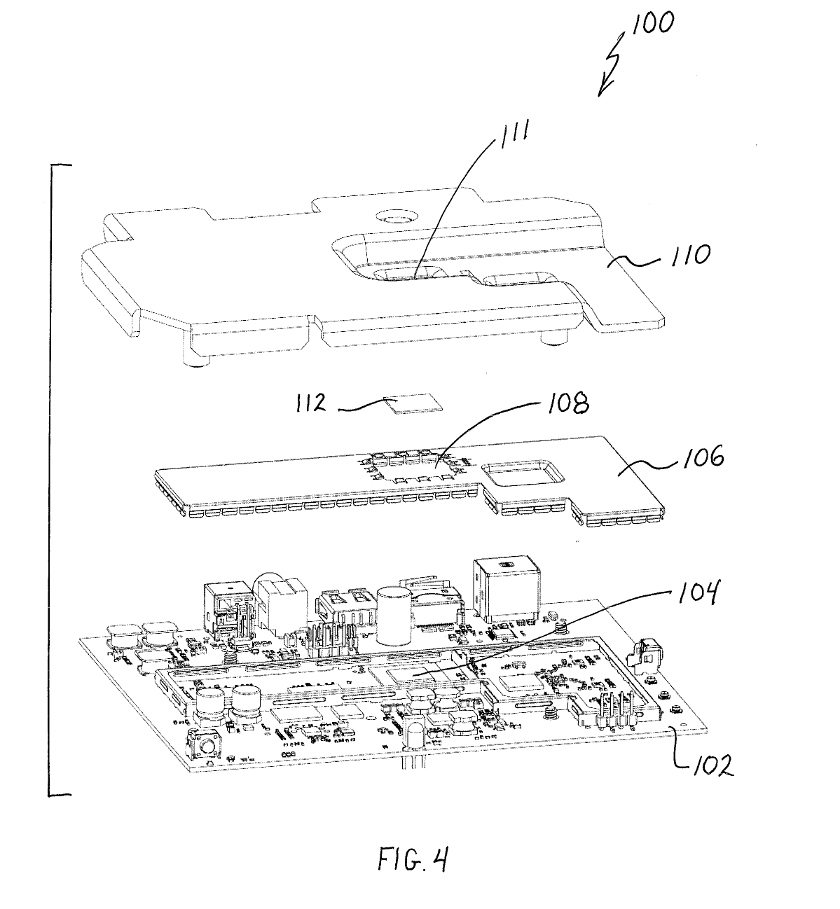

As illustrated in FIG. 1, an electronic device 10 of the prior art is made up of a printed circuit board (PCB) 12, a shield 16 and heatsink or heat spreader 20. The PCB 12 includes many components, some of which generate more heat than others and which require heatsinks to aid in the dissipation of that heat during operation. One example of such components is identified as reference 104 in FIG. 4.

Generally speaking, those of skill in the art will appreciate that the shield 16 is configured to shield part of the PCB components from the other components on the PCB for various reasons, but primarily to shield radio frequency interference from either radiating onto surrounding components from components contained within the shield, or generated by components outside the shield from affecting those components within the shield.

According to one implementation, the electronic device of the present principles would be a set top box generally provided to customers through respective content providers. In other implementations, the electronic device of the present principles can be a gateway device used to assist in the transmission of content to or from a customer or content source provider, respectively. Those of skill in the art will appreciate that other implementations of the present principles into many different types of electronic devices can be made without departing from the intended scope of the same.

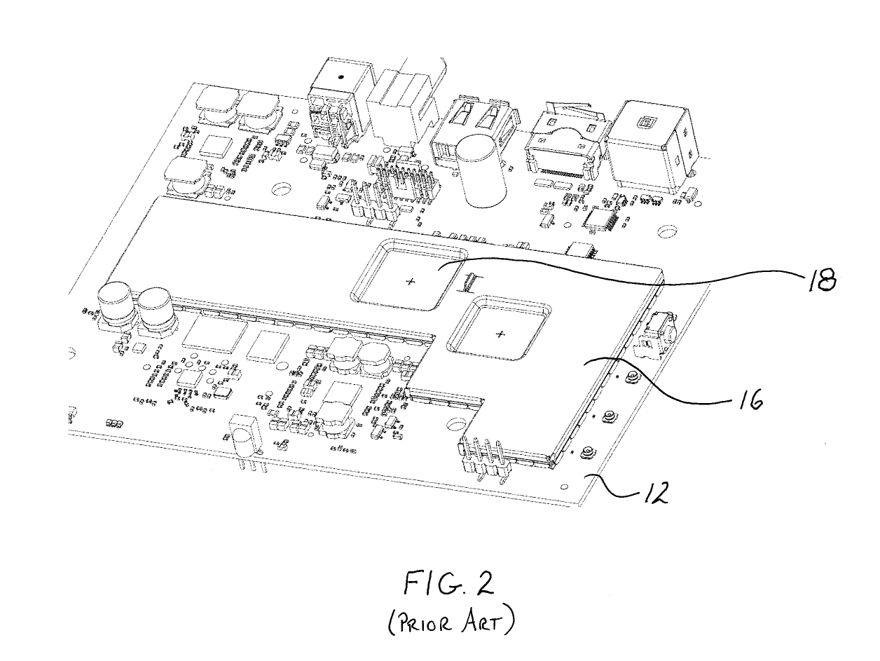

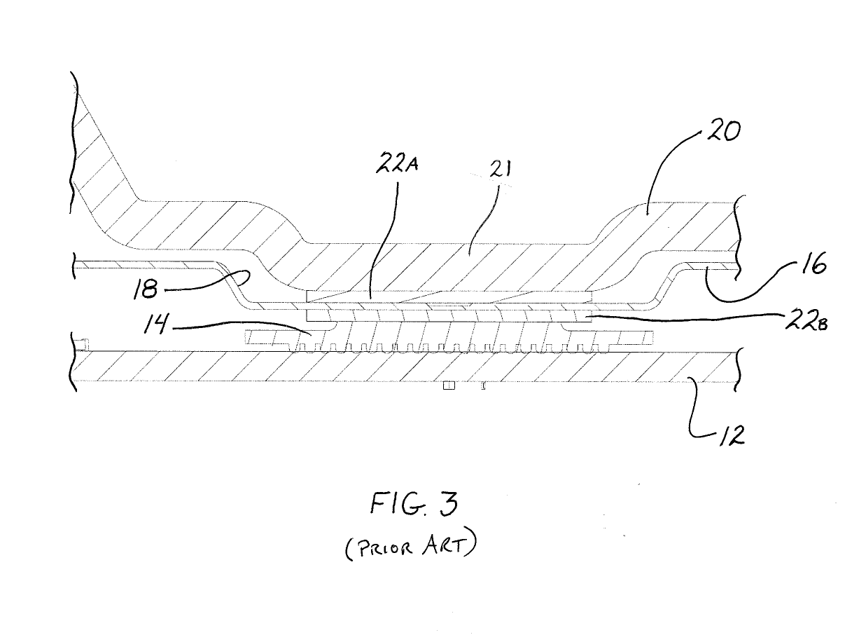

Referring to FIGS. 1-3, the shield 16 includes one or more embossments 18 which are positioned over the components 14 requiring heat dissipation. Thermo pads 22A, 22B are used to transfer the heat from component 14 to the heatsink 20. As shown in FIG. 3, the underside of thermo pad 22B is positioned directly on the component 14. The upper side of thermo pad 22B is in direct thermal contact with the embossment 18 of the shield 16, and an upper thermo pad 22A is in direct contact with the embossment 18 on its bottom side and the depression 21 in the heatsink 20 on the upper side. (See FIG. 3). In this manner, heat generated by component 14 is transferred via thermo pad 22B, embossment 18, and thermo pad 22A to the heatsink or heat spreader 20. Although this known design is effective for heat transfer from the components, a significant problem arises in the proper grounding of the heatsink 20 with respect to the PCB. Such grounding problems can interfere in many aspects of the operation of the electronic device, not the least of which is damage to one or more of the electronic components on the PCB, ultimately resulting in failed operation of the electronic device 10.

Referring to FIG. 4, there is shown an electronic device 100 according to an implementation of the present principles. The electronic device 100 is made up of a printed circuit board (PCB) 102, a shield 106 and heatsink or heat spreader 110. In this implementation, the shield 106 includes an open window 108 (hereinafter referred to as the “heat transfer window”) where a thermo-coupling between a component 104 and heatsink 110 will be made.

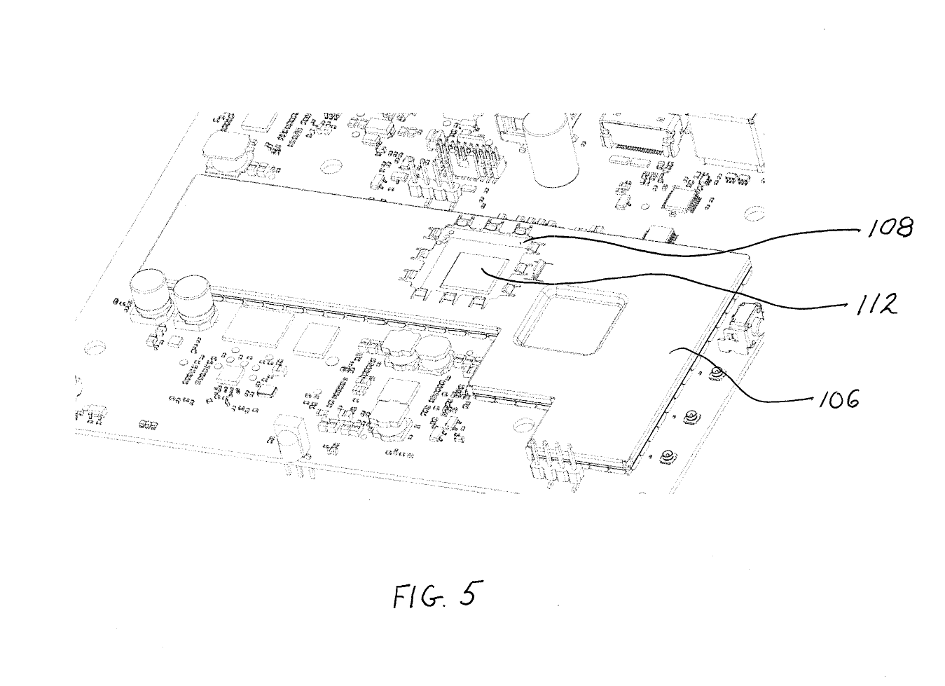

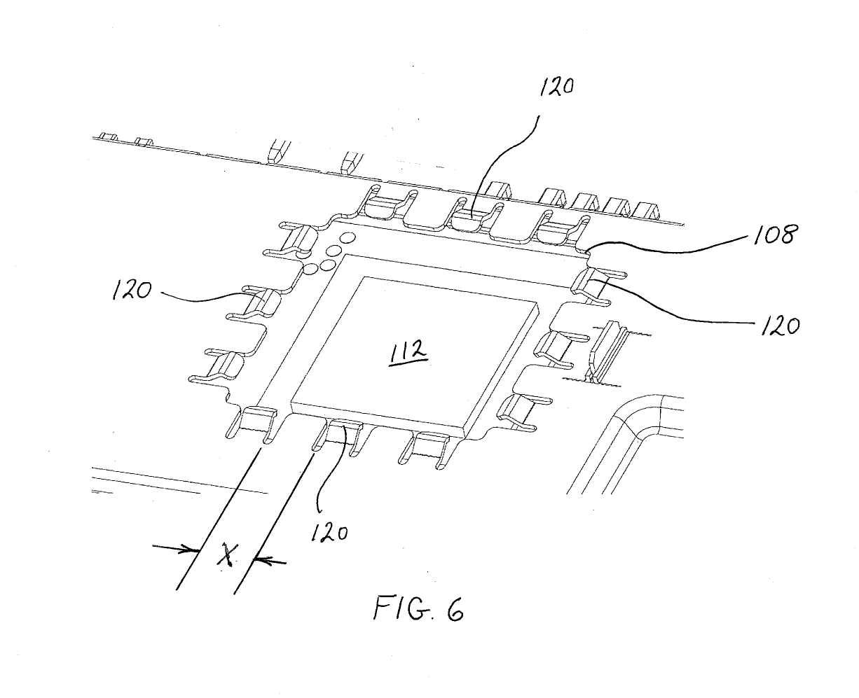

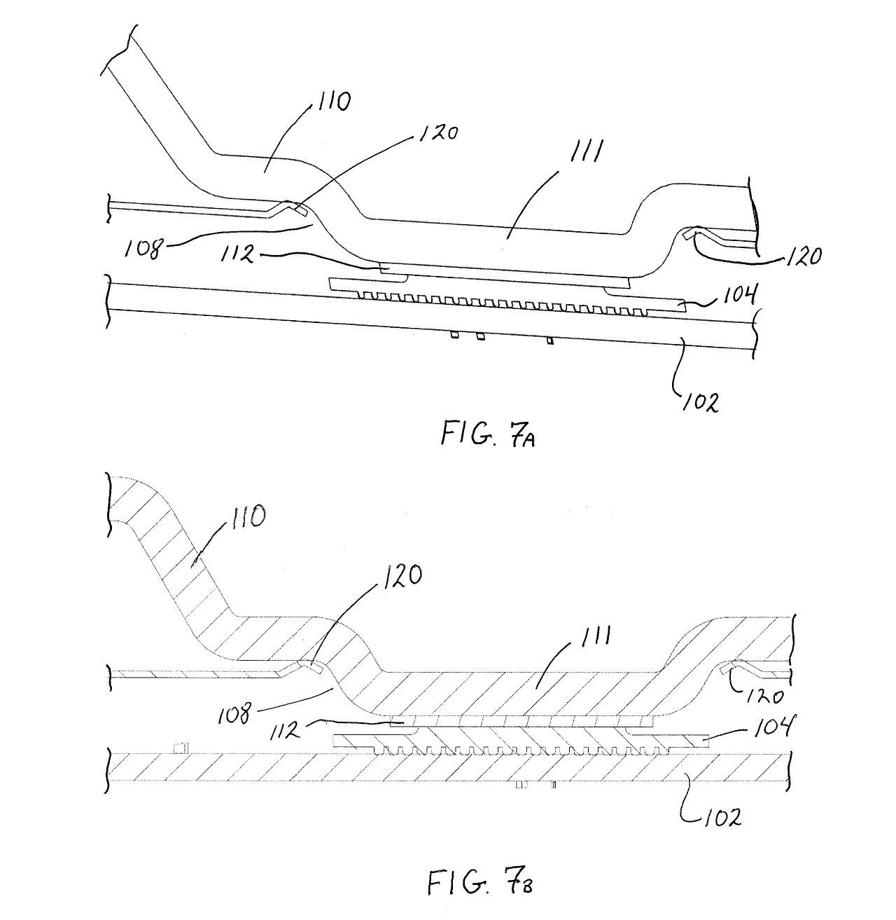

FIGS. 5 and 6 show a view of the shield 106 in its operable position on the PCB 102. As shown, the heat transfer window 108 is aligned with the component 104 (FIGS. 4 and 7) and the thermo pad 112 is positioned over the same. The shield 106 can include a plurality of ground fingers 120 positioned around the periphery of the heat transfer window 108. The ground fingers 120 are spring biased and protrude upward from the planar surface of the shield 106 and are configured to physically engage the depression 111 in the heatsink 110. The upward spring bias of the ground fingers 120 assures consistent and accurate physical and electrical contact between the shield 106 and heatsink 110, via depression 111.

FIGS. 7A and 7B show a side view and cross-sectional view, respectively, of the assembled electronic device 100 according to an implementation of the present principles. As shown, as a result of the heat transfer window 108 in shield 106, the depression 111 of the heatsink 110 passes through the window 108 and directly contacts the thermo pad 112 positioned on component 104. Thus, it will be apparent that this thermo-coupling and thereby the thermal conductivity of the component 104 to the heatsink 110 is improved. This design provides more efficient heat transfer than that of the prior art, by eliminating one thermo pad and the shield layer (i.e., layer of sheet metal) which would otherwise be present in the thermo path to affect this thermo-coupling.

Importantly, the ground fingers 120 around the periphery of the heat transfer window 108 physically and electronically couple the shield 106 to the heatsink 110. In this manner, the aforementioned problems associated with grounding of the heatsink 110 are eliminated and the heatsink is now sufficiently grounded to the PCB, via the ground fingers 120 of shield 106. In addition, once assembled, any potential losses in shielding created by the window 108 are eliminated by the fixation of the heatsink with depression 111 passing through the window 108. Those of skill in the art will appreciate that the metallic, electrically conductive body of the heatsink functionally closes the open heat transfer window 108. The ground fingers 120 are therefore spaced close enough together to prevent gaps larger than a selected maximum wavelength of a wavelength range which can be deemed to be detrimental, thereby effectively attenuating or blocking radiation wavelengths of radiation above that spacing size. FIG. 6 shows an example of the spacing X between adjacent ground fingers 120 selected so as to maintain the desired shielding effect of the shield based on the selected maximum wavelength. By way of example, a general rule can be applied where an aperture at 1/10 of a particular wavelength will attenuate or block 90% of the radiation of that wavelength incident on the aperture and attenuate more than 90% above that wavelength. Those of skill in the art will appreciate that “aperture” as used in the above example is analogous to applicant's spacing X between adjacent ground fingers 120. As such, the same concepts apply to the present principles.

Those of skill in the art will appreciate that the physical form of ground fingers 120 may be different than that shown in the figures without departing from the intended scope of the present principles, provided such fingers are configured to consistently make a good physical and electrical connection with the corresponding heatsink/heat spreader. In one preferred implementation, the ground fingers 120 are spring biased upward such that the heatsink 110 will be forced downward against such spring bias when assembling the electronic device, thus assuring proper physical and electrical contact.

The foregoing illustrates some of the possibilities for practicing the present principles. Many other embodiments are possible within the scope and spirit of the present principles. It is, therefore, intended that the foregoing description be regarded as illustrative rather than limiting, and that the scope of the present principles is given by the appended claims together with their full range of equivalents.

1. An electronic device having a printed circuit board having one or more electronic components requiring heat dissipation, the electronic comprising:
a shield configured to be positioned on at least a part of the printed circuit board and having one or more heat transfer windows positioned over the one electronic components requiring heat dissipation; and
a heatsink having one or more depressions configured to be positioned over and pass through the one or more heat transfer windows in the shield.

2. The electronic device of claim 1, further comprising one or more thermo pads having one side positioned directly on the one or more components requiring heat dissipation, said one or more depressions in said heatsink physically contacting an opposing side of said one or more thermo pads through said heat transfer window of the shield.

3. The electronic device of claim 1, wherein the shield comprises grounding connections positioned around each of the one or more heat transfer windows, said grounding connections grounding the heatsink to the printed circuit board when said one or more depressions pass through its respective one or more heat transfer windows.

4. The electronic device of claim 3, wherein said grounding connections comprise ground fingers positioned around a periphery of each of the one or more heat transfer windows.

5. The electronic device of claim 4, wherein said ground fingers are upwardly biased with respect to a planar surface of the shield to ensure electrical contact with the respective one or more depressions in the heatsink.

6. The electronic device of claim 3, further comprising a spacing between said ground connections, said spacing being selected based on radio frequency wavelengths to be blocked by said shield.

7. An electronic device comprising:
a printed circuit board having one or more electronic components;
a shield configured to be positioned on at least a part of the printed circuit board and, the shield comprising:
at least one open heat transfer window positioned to be aligned with at least one electronic component requiring heat dissipation; and
a ground connection associated with the at least one open heat transfer window; and
a heatsink having at least one depression configured to be aligned with the at least one open heat transfer window.

8. The electronic device according to claim 7, wherein the ground connection comprises a plurality of ground fingers positioned around a periphery of the heat transfer window, said plurality of ground fingers configured to physically engage the heatsink around the at least one depression and thereby ground the heatsink to the printed circuit board.

9. The electronic device according to claim 7, further comprising a thermo pad having one side positioned directly on the at least one component requiring heat dissipation, said at least one depression in said heatsink physically contacting an opposing side of said thermo pad by passing through said at least one heat transfer window of the shield.

10. The electronic device according to claim 8, wherein said plurality of ground fingers comprise a predetermined spacing between each of the same, said predetermined spacing being selected based on radio frequency wavelengths to be blocked by the shield.

11. The electronic device according to claim 8, wherein said plurality of ground fingers are upwardly biased with respect to a planar surface of the shield to ensure electrical contact with the respective one or more depressions in the heatsink.
